(19) United States
(12) Patent Application Publication
(10) Pub. No.: US 2014/0097432 A1
(43) Pub. Date: Apr. 10, 2014

(54) SHEET OF SEMICONDUCTING MATERIAL, LAMINATE, AND SYSTEM AND METHODS FOR FORMING SAME

(71) Applicant: Corning Incorporated, Corning, NY (US)

(72) Inventors: Samir Biswas, Horseheads, NY (US); Douglass Lane Blanding, Painted Post, NY (US); Glen Bennett Cook, Elmira, NY (US); Prantik Mazumder, Ithaca, NY (US); Kamal Kishore Soni, Painted Post, NY (US); Balram Suman, Katy, TX (US)

(73) Assignee: Corning Incorporated, Corning, NY (US)

(21) Appl. No.: 13/842,113

(22) Filed: Mar. 15, 2013

Related U.S. Application Data
(60) Provisional application No. 61/711,512, filed on Oct. 9, 2012.

(51) Int. Cl. H01L 21/02

(52) U.S. Cl. CPC H01L 21/02422
USPC 257/49; 118/419; 438/479

(57) ABSTRACT

Methods of forming a laminate comprising a sheet of semiconductor material utilize a system. The system comprises a fibrous sheet, a guide member for guiding the fibrous sheet, and a melt of a semiconductor material. The sheet of semiconductor material and a laminate comprising the fibrous sheet and the sheet of semiconductor material are also included.

### CROSS-REFERENCE TO RELATED APPLICATIONS

This application claims the benefit of priority under 35 U.S.C. §119 of U.S. Provisional Application Ser. No. 61/711,512 filed on Oct. 9, 2012, the content of which is relied upon and incorporated herein by reference in its entirety.

### BACKGROUND

The disclosure relates to methods of forming a sheet of semiconductor material, a system for forming the sheet of semiconductor material, and a laminate and a sheet of semiconductor material formed with the methods.

Semiconductor materials are used in a variety of applications, and may be incorporated, for example, into electronic devices such as photovoltaic devices. The properties of semiconductor materials may depend on a variety of factors, including crystal structure, the concentration and type of intrinsic defects, and the presence and distribution of dopants and other impurities. Within a semiconductor material, the grain size and grain size distribution, for example, can impact the performance of resulting devices. One type of semiconductor material is silicon, which may be formed via a variety of techniques, e.g. as an ingot, sheet or ribbon. The silicon may be supported or unsupported by an underlying substrate.

Small sheets of semiconductor materials can be prepared by a variety of batch methods. One batch method of forming such small sheets is referred to as an exocasting process in which a mold having a small shape that can be placed into a crucible is dipped into a melt of a semiconductor material disposed in the crucible. The mold is then removed from the melt of the semiconductor material and a small sheet forms on surfaces of the mold, which can subsequently be removed and refined or otherwise utilized. However, the sheet of the semiconductor material formed in such conventional methods is limited in dimension based on the size of the mold utilized, and thus these conventional methods can be particularly time consuming to obtain a significant volume of the small sheets of the semiconductor materials. Further, such conventional methods are batch processes, which further limit a rate at which sheets of semiconductor materials can be prepared.

### SUMMARY

The disclosure provides methods of forming a laminate comprising a sheet of semiconductor material. The method employs a system which comprises a fibrous sheet, a guide member for guiding the fibrous sheet, and a melt of a semiconductor material.

In a first embodiment, the method comprises contacting an undersurface of the fibrous sheet with the melt of the semiconductor material as the fibrous sheet is guided by the guide member such that the sheet of semiconductor material is formed on the undersurface of the fibrous sheet to give the laminate. In this embodiment, the laminate comprises the sheet of semiconductor material in contact with the undersurface of the fibrous sheet.

In a second embodiment, the method comprises contacting a surface of the fibrous sheet with the melt of the semiconductor material as the fibrous sheet is guided by the guide member such that the sheet of semiconductor material is formed on the surface of the fibrous sheet to give the laminate. In this embodiment, the laminate comprises the sheet of semiconductor material in contact with the surface of the fibrous sheet. In addition, in this embodiment, the fibrous sheet comprises a material selected from fused silica, silicon nitride, mullite, magnesium aluminate, and combinations thereof.

The disclosure also provides a system for forming the sheet of semiconductor material with the methods. The disclosure further provides a laminate comprising the sheet of semiconductor material in contact with the surface of the fibrous sheet, the laminate being formed in accordance with the methods. Finally, the disclosure provides a sheet of semiconductor material formed in accordance with the methods.

### BRIEF DESCRIPTION OF THE DRAWINGS

Other advantages and aspects may be described in the following detailed description when considered in connection with the accompanying drawings wherein:

FIG. 1 is a schematic cross-sectional view of one embodiment of a system for forming a sheet of semiconductor material;

FIG. 2 is a schematic view of another embodiment of the system for forming the sheet of semiconductor material;

FIG. 3 is a schematic view of certain aspects of one embodiment of the system; and

FIG. 4 is a graph illustrating thickness of a sheet of semiconductor material in one embodiment of the disclosure as a function of pulling speed.

### DETAILED DESCRIPTION OF THE DISCLOSURE

Referring to the Figures, wherein like numerals indicate like parts throughout the several views, a system in accordance with the instant disclosure is shown generally at 10. The disclosure provides methods of forming a laminate 12 comprising a sheet of semiconductor material 14 with the system 10. The disclosure also provides the system 10 for forming the sheet of semiconductor material 14 in accordance with the methods. Finally, the disclosure provides a sheet of semiconductor material 14 and the laminate 12 formed with the methods. The sheet of semiconductor material 14 formed via the methods is particularly suitable for electronics applications and components, such as microprocessors and photovoltaic cell modules.

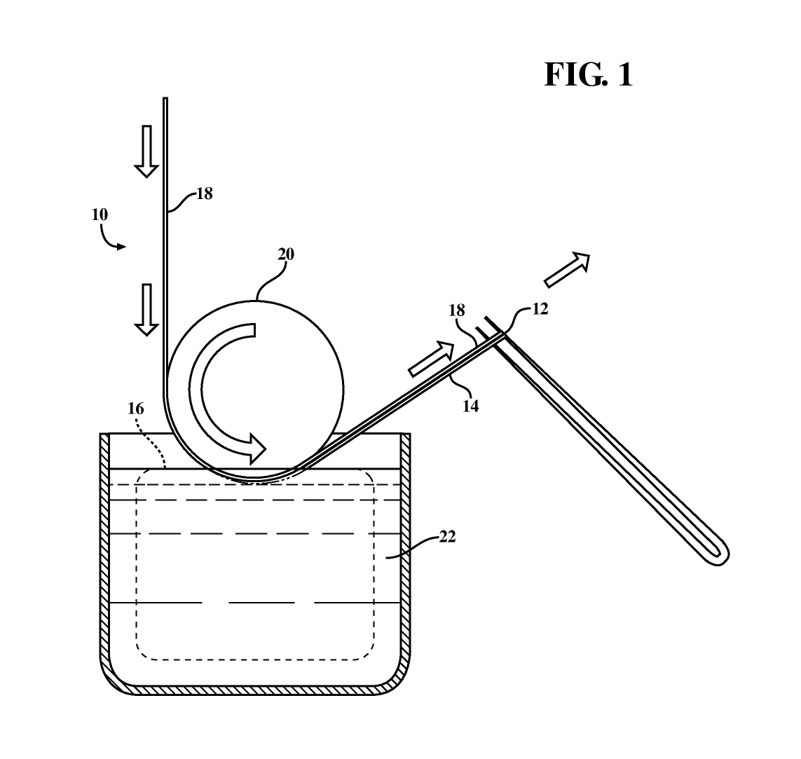

The system 10 is utilized to form the sheet of semiconductor material 14 from a melt of a semiconductor material 16. The system 10 comprises a fibrous sheet 18, a guide member 20 for guiding the fibrous sheet 18, and the melt of the semiconductor material 16, as illustrated in FIG. 1.

In a first embodiment, the method comprises contacting an undersurface of the fibrous sheet 18 with the melt of the semiconductor material 16 as the fibrous sheet 18 is guided by the guide member 20 such that the sheet of semiconductor material 14 is formed on the undersurface of the fibrous sheet 18 to give the laminate 12. In this embodiment, the laminate 12 comprises the sheet of semiconductor material 14 in contact with the undersurface of the fibrous sheet 18.

In a second embodiment, the method comprises contacting a surface of the fibrous sheet 18 with the melt of the semiconductor material 16 as the fibrous sheet 18 is guided by the guide member 20 such that the sheet of semiconductor material 14 is formed on the surface of the fibrous sheet 18 to give the laminate 12. In this embodiment, the laminate 12 comprises the sheet of semiconductor material 14 in contact with the surface of the fibrous sheet 18. In addition, in this embodiment, the fibrous sheet 18 comprises a material selected from fused silica, silicon nitride, mullite, magnesium aluminate, and combinations thereof.

Various aspects of the methods of the first and second embodiments introduced above are described collectively in detail below, unless otherwise indicated.

Without being bound by theory, due in large part to heat loss to the fibrous sheet 18, the guide member 20, and/or the surroundings, at least a portion of the melt of the semiconductor material 16 undergoes a liquid-to-solid phase transformation, which results in the formation of the sheet of semiconductor material 14 on the surface of the fibrous sheet 18 to give the laminate 12. In the system 10, the fibrous sheet 18 and/or the guide member 20 act as a heat sink, and the fibrous sheet 18 acts as a solid form (or mold) for the solidification to occur.

Regardless of the method utilized, the fibrous sheet 18 of the system 10 comprises a plurality of fibers, alternatively a single fiber. The fiber(s) of the fibrous sheet 18 may be woven or nonwoven. The fiber(s) of the fibrous sheet 18 have sufficient physical properties for forming the sheet of semiconductor material 14 on the surface of the fibrous sheet 18. Further, the fiber(s) of the fibrous sheet 18, and thus the fibrous sheet 18 itself, are compatible with the melt of the semiconductor material 16. For example, the fiber(s) and the fibrous sheet 18 are compatible with the melt of the semiconductor material 16 if the fiber(s) and the fibrous sheet 18 do not melt or soften from exposure to heat from the melt of the semiconductor material 16, or otherwise substantially degrade from exposure to heat from the melt of the semiconductor material 16 during the methods. The fiber(s) and the fibrous sheet 18 may be thermally stable and/or chemically inert to the melt of the semiconductor material 16, and therefore non-reactive or substantially non-reactive with the melt of the semiconductor material 16. In addition, the fiber(s) are typically selected so as to avoid, prevent, or minimize the fiber(s) and the fibrous sheet 18 contaminating the melt of the semiconductor material 16. Further, the fiber(s) have mechanical properties such as strength or modulus that generally impart the fibrous sheet 18 with sufficient strength to withstand various tensile forces associated with the method, yet the fibrous sheet 18 is typically flexible such that the fibrous sheet 18 can be rolled or spooled.

The fiber(s) may be made from a single material, alternatively from a blend of two or more different materials. The blend of materials may be homogenous, alternatively heterogeneous. Specific examples of materials suitable for the fiber(s) of the fibrous sheet 18 in the first embodiment include refractory materials such as fused silica, graphite, silicon nitride, silicon carbide, mullite, magnesium aluminate, and combinations thereof. However, in the second embodiment, the fibrous sheet 18 comprises a material selected from fused silica, silicon nitride, mullite, magnesium aluminate, and combinations thereof.

The fiber(s) may comprise combinations and composites of these materials. For example, different fibers within the fibrous sheet 18 may independently comprise any of these refractory materials. Further, when a single fiber is employed in the fibrous sheet 18, the single fiber may vary in its composition. In certain embodiments, the fiber(s) independently comprise vitreous silica, independent of the particular method utilized.

The fiber(s) of the fibrous sheet 18 may independently be porous or non-porous, optionally having one or more porous or non-porous coatings.

The fibrous sheet 18 may be woven, nonwoven, or combinations thereof. For example, when the fibrous sheet 18 is woven, the fiber(s) of the fibrous sheet 18 may be interlaced with one another such that the fibrous sheet 18 comprises a web of fiber(s) wherein certain fiber(s) (or portions of fiber(s)) are substantially parallel with one another (or with another portion of the same fiber) and certain fiber(s) (or portions of fiber(s)) are substantially perpendicular to one another (or to another portion of the same fiber). Alternatively, the angles between certain fiber(s) may be other than perpendicular, e.g. acute or obtuse. Accordingly, when the fibrous sheet 18 is woven, the fibrous sheet 18 generally has a defined pattern. Such woven fibrous sheet 18 may be prepared with the fiber(s) via known methods of weaving fiber(s). Alternatively, when the fibrous sheet 18 is nonwoven, the fiber(s) of the fibrous sheet 18 are generally entangled with one another such that the fibrous sheet 18 comprises a web of fiber(s) that are bonded together mechanically, thermally, and/or chemically. When the fibrous sheet 18 is nonwoven, the fiber(s) are generally randomly entangled with one another (or a single fiber may be entangled with itself) without a defined pattern. Adjacent fibers that are in contact with one another may be fused to one another (e.g. at their nodes), alternatively in contact with one another but not fused or otherwise bonded to one another, or combinations thereof.

The fiber(s) may also be characterized by features including shape, dimension, surface area, surface roughness, construction, etc. One or more of these features may be uniform or non-uniform. The dimensions of the fiber(s), particularly a thickness of the fiber(s), are generally selected based on a desired surface pattern of the sheet of semiconductor material 14. In particular, the sheet of semiconductor material 14 typically has a surface roughness and texture imparted by the fibrous sheet 18. The desired surface roughness and texture of the sheet of semiconductor material 14 may vary based on an application or component in which the sheet of semiconductor material 14 is utilized. In certain embodiments, the fiber(s) of the fibrous sheet 18 have an average thickness of from greater than 0 to 200, alternatively from 9 to 100, alternatively from 9 to 20, micrometers (μm). Alternatively, the fiber(s) of the fibrous sheet 18 may have varying thicknesses and sizes contingent on the desired surface pattern of the sheet of semiconductor material 14. The fiber(s) may independently have a cross-sectional shape that is elliptical, spherical, square, rectangular, or other various shapes. The thickness referenced above refers to a greatest dimension perpendicular to a length of the fiber(s). The fiber construction in cross-section may be mono-component, alternatively multi-component. The multi-component fibers may be bicomponent, alternatively 3-component or more. The bicomponent fibers may have a cross-section that is sheath-core, matrix-fibril, islands-in-the-sea, or side-by-side.

The guide member 20 of the system 10 is for guiding the fibrous sheet 18. The terms “guide” and “guiding,” as used herein with reference to the guide member 20 guiding the fibrous sheet 18, means that the guide member 20 at least partially determines a position of the fibrous sheet 18. For example, the guide member 20 may merely be a static, i.e., stationary, member in contact with the fibrous sheet 18. Said differently, the term “guiding” does not require any motion or action from or by the guide member 20.

The fibrous sheet 18 has a second surface opposite the surface that contacts the melt of the semiconductor material 16. In the first embodiment, the second surface is a topside of the fibrous sheet 18 because the underside of the fibrous sheet 18 contacts the melt of the semiconductor material 16. However, in the second embodiment, the second surface may be either the topside or the underside of the fibrous sheet 18. The second surface of the fibrous sheet 18 is typically in contact with the guide member 20 such that a portion of the fibrous sheet 18 is disposed between the guide member 20 and the melt of the semiconductor material 16 in the system 10.

The system 10 typically defines a contact point between the fibrous sheet 18 and the guide member 20. The surface of the fibrous sheet 18 opposite the contact point generally contacts the melt of the semiconductor material 16, as described below with reference to the method. In particular, the second surface of the fibrous sheet 18 contacts the guide member 20 at the contact point, and the surface opposite the second surface of the fibrous sheet 18 contacts the melt of the semiconductor material 16.

The guide member 20 can be any member having a shape allowing for the fibrous sheet 18 to contact the melt of the semiconductor material 16. The relative location of the contact point between the guide member 20 and the fibrous sheet 18 is typically contingent on external surfaces of the guide member 20. For example, the external surfaces of the guide member 20 may be rectangular or otherwise present an acute or obtuse external portion for contacting the second surface of the fibrous sheet 18 and for guiding the fibrous sheet 18. When the external surfaces of the guide member 20 are rectangular, a corner or edge of the guide member 20 is in contact with the second surface of the fibrous sheet 18 at the contact point. Alternatively, the guide member 20 may have a trapezoidal or triangular shape wherein an obtuse or acute angle of the external surfaces of the guide member 20 is contact with the second surface of the fibrous sheet 18 at the contact point. The contact point is typically not linear or parallel with a level surface of the melt of the semiconductor material 16 to ensure that the fibrous sheet 18 properly contacts the melt of the semiconductor material 16 on the surface opposite the second surface of the fibrous sheet 18 which defines the contact point.

The guide member 20 may be stationary and motionless. For example, when the guide member 20 is rectangular and a corner of the guide member 20 is in contact with the fibrous sheet 18, the guide member 20 may be stationary as the sheet of semiconductor material 14 is formed on the surface of the fibrous sheet 18. Alternatively, in certain embodiments, the guide member 20 extends along an axis and the guide member 20 is rotatable about the axis such that the guide member 20 rotates as the sheet of semiconductor material 14 is formed on the surface of the fibrous sheet 18. In these embodiments, the contact point is generally located at the same location in the system 10 during the method, but different portions of the external surfaces of the guide member 20 are in contact with the fibrous sheet 18 as the guide member 20 rotates, i.e., even though the contact point is static in the system 10, the contact point is continuously defined by a different portion of the guide member 20 and a different portion of the second surface of the fibrous sheet 18.

In certain embodiments, the guide member 20 comprises a convex member extending along an axis. In these embodiments, the external surfaces of the convex member have a convex shape. The convex member need not have the entirety of its external surfaces present the convex shape. For example, the convex member be cylindrical, partially cylindrical, elliptical, partially elliptical, partially spherical, or may be any shape having an arced portion to provide the convex shape. The convex member has a perimeter and may be generally rectangular wherein from greater than 0 to less than 360 degrees of the perimeter, i.e., the external surfaces, has the arced portion to present the convex shape. The arced portion of the convex member is generally in contact with the second surface of fibrous sheet 18 to define the contact point.

As with the guide member 20 described above, the convex member may be stationary and motionless relative to its axis. For example, when the arced portion of the convex member is in contact with the second surface of the fibrous sheet 18, the convex member may be stationary as the sheet of semiconductor material 14 is formed on the surface of the fibrous sheet 18. Alternatively, in certain embodiments, the convex member is rotatable about the axis such that the convex member rotates as the sheet of semiconductor material 14 is formed on the surface of the fibrous sheet 18. In these embodiments, the convex member is typically cylindrical such that the convex member presents a continuously arced surface for allowing consistent rotation of the convex member without altering a location of the contact point in the system 10, which may undesirable impart the sheet of semiconductor material 14 with various non-uniform properties, such as thickness. For example, in such embodiments, the convex member may be a cylindrical roller extending along the axis. When viewed at the contact point, the rotation of the convex member may be codirectional, alternatively contradirectional, with the movement of the fibrous sheet 18.

Regardless of the guide member 20 utilized in the system 10, the guide member 20 may be solid, hollow, or combinations thereof. For example, when the guide member 20 is the cylindrical roller, the cylindrical roller may have a hollow interior such that the cylindrical roller has a tube shape or the cylindrical roller may be solid. When the guide member 20 is hollow or otherwise defines an empty volumetric space, e.g. a cavity, within its interior, the guide member 20 may optionally be cooled before, during, and/or after the method. For example, a coolant, such as water, may be fed through or into the hollow interior or empty space within the guide member 20 to remove heat from the guide member 20 during the method, which is generally attributable to heat transfer from the melt of the semiconductor material 16.

The guide member 20 may comprise a continuous surface material or combinations of different materials. The guide member 20 generally comprises a surface material that is compatible with the fibrous sheet 18 and the melt of the semiconductor material 16. Compatibility relative to the melt of the semiconductor material 16 is described above with respect to the fibrous sheet 18.

The guide member 20 may comprise the same material as the fibrous sheet 18 or may comprise a material different than the material of the fibrous sheet 18. Specific examples of surface materials suitable for the guide member 20 include the refractory materials described above, as well as vitreous carbon, diamond-like carbon, and similar forms of carbon. In certain embodiments, the guide member 20 comprises vitreous silica.

When guide member 20 comprises a combination of materials, at least a portion of guide member 20 comprises at least one of the refractory materials above. In such embodiments, the external surfaces of the guide member 20 that contacts the second surface of the fibrous sheet 18 comprises at least one of these refractory materials. As such, in certain embodiments, only a portion of the external surfaces of the guide member 20 comprises at least one of these refractory materials (e.g. the arced portion). However, when the guide member 20 is rotatable about the axis such that the entire external surfaces of the guide member 20 at one point contacts the second surface of the fibrous sheet 18 as the guide member 20 rotates, the external surfaces of the guide member 20 in its entirety typically comprises at least one refractory material.

When the guide member 20 comprises a combination of materials, the guide member 20 may further comprise materials that are suitable for supporting the refractory materials. For example, the refractory materials may be utilized in combination with metals, alloys, ceramics, and composites and/or combinations thereof. When such combinations are utilized in the guide member 20, the relative thickness of the refractory materials in the guide member 20 is a factor of, among other things, the desired heat transfer kinetics between the guide member 20 and the melt of the semiconductor material 16. To this end, different refractory materials have different specific heat capacities, and thus the relative thickness of the refractory materials in the guide member 20 is also a factor of the particular refractory materials utilized. As one specific example, when the guide member 20 comprises vitreous silica, the relative thickness of the refractory materials in the guide member 20 is typically at least about 250 micrometers (μm). Alternatively, when the guide member 20 comprises silicon carbide, the relative thickness of the refractory materials in the guide member 20 is typically at least about 170 micrometers (μm) because silicon carbide has a much greater specific heat capacity than vitreous silica.

The refractory materials of the guide member 20 may be in the form of a monolith or wafer. Further, the refractory materials of the guide member 20 may comprise a porous or a non-porous body, optionally having one or more porous or non-porous coatings. The refractory materials of guide member 20 may be characterized by features including shape, dimension, surface area, surface roughness, etc. One or more of these features may be uniform or non-uniform.

The melt of the semiconductor material 16 is generally disposed in a vessel 22, such as a crucible. The melt of the semiconductor material 16 may be provided or obtained by melting a suitable semiconductor material in the vessel 22. The vessel 22 is generally formed from a high temperature or refractory material chosen from vitreous silica, graphite, silicon carbide, vitreous carbon, and silicon nitride. Alternatively, the vessel 22 may be formed from a first high temperature or refractory material and provided with an internal coating of a second high temperature or refractory material where the internal coating is adapted to be in contact with the melt of the semiconductor material 16. The semiconductor material may be silicon. In addition to silicon or alternatively, the melt of the semiconductor material 16 may be chosen from alloys and compounds of silicon, germanium, alloys and compounds of germanium, gallium arsenide, alloys and compounds of gallium arsenide, and combinations thereof. For example, the silicon may be pure, e.g., intrinsic or i-type silicon; alternatively the silicon may be doped, e.g., silicon containing an n-type or p-type dopant.

The melt of the semiconductor material 16 may comprise at least one non-semiconducting element that may form a semiconducting alloy or compound. For example, the melt of the semiconductor material 16 may comprise gallium arsenide (GaAs), aluminum nitride (AlN) or indium phosphide (InP).

According to various embodiments, the melt of the semiconductor material 16 may be pure or doped. Example dopants, if present, include boron, phosphorous, or aluminum, and may be present in any suitable concentration, e.g. 1-100 ppm, which may be chosen based on, for example, the desired dopant concentration in the sheet of semiconductor material 14.

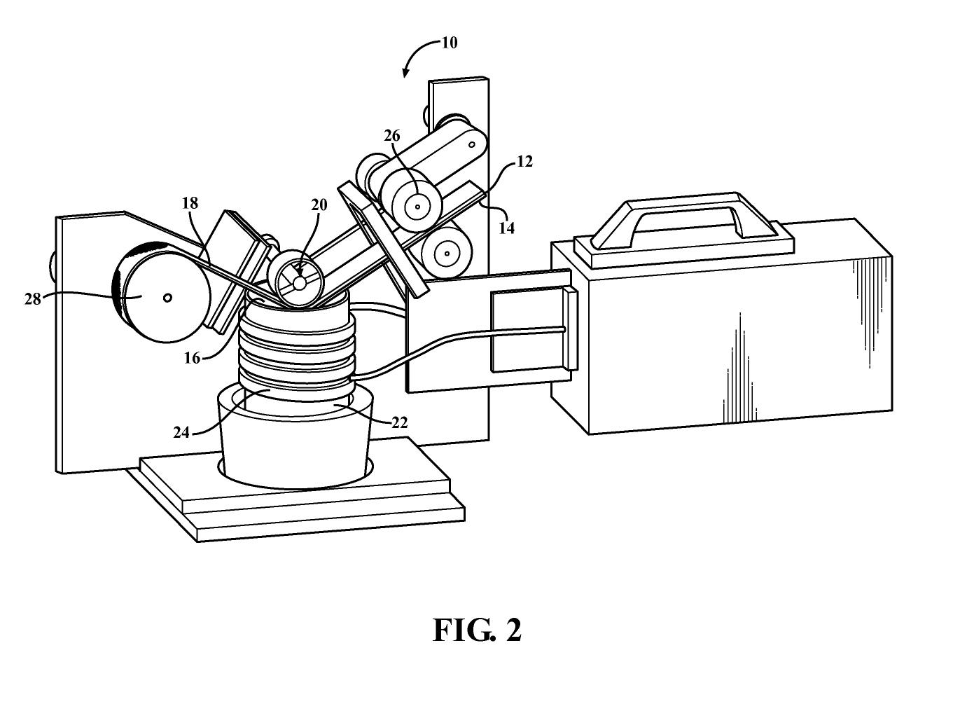

As shown in FIG. 2, at least one heating element 24 may be utilized to form the melt of the semiconductor material 16 and/or maintain the melt of the semiconductor material 16 at a desired temperature. Examples of suitable heating elements include resistive or inductive heating elements, infrared (IR) heat sources (e.g., IR lamps), and flame heat sources. An example of an inductive heating element is a radio frequency (RF) induction heating element. RF induction heating may provide a cleaner environment by minimizing the presence of foreign matter in the melt of the semiconductor material 16.

As noted above, the method comprises contacting the surface of the fibrous sheet 18 with the melt of the semiconductor material 16 as the fibrous sheet 18 is guided by the guide member 20 such that the sheet of semiconductor material 14 is formed on the surface of the fibrous sheet 18 to give the laminate 12.

The manner in which the guide member 20 guides the fibrous sheet 18 is contingent on the guide member 20 utilized in the system 10.

For example, when the guide member 20 is fixed, i.e., stationary and motionless, the method typically further comprises pulling the fibrous sheet 18 in a direction generally tangential to the contact point between the guide member 20 and the second surface of the fibrous sheet 18. In such embodiments, the guide member 20 guides the fibrous sheet 18 merely by forcing the surface of the fibrous sheet 18 to contact the melt of the semiconductor material 16. For example, when the guide member 20 is rectangular and a corner of the guide member 20 is in contact with the second surface of the fibrous sheet 18, the guide member 20 is typically positioned such that the corner of the guide member 20 is positioned immediately above or in nominal contact with the surface level of the melt of the semiconductor material such that as the fibrous sheet 18 is pulled, the guide member 20 continuously forces the surface of the fibrous sheet 18 opposite the contact point to contact the melt of the semiconductor material 16. A similar configuration of the system 10 is generally employed when the system 10 utilizes the convex member that is stationary and motionless, or even when the guide member 20 rotates about its axis, as the guide member 20 guides the fibrous sheet 18.

When the guide member 20 extends along the axis and it is rotatable about the axis, the guide member 20 typically guides the fibrous sheet 18 by, among other things, rotating about the axis. For example, when the guide member 20 is the cylindrical roller that is rotatable about its axis, the guide member 20 is typically positioned such that the external surfaces of the cylindrical roller is positioned immediately above or in nominal contact with the surface level of the melt of the semiconductor material 16. As the cylindrical roller rotates, the cylindrical roller continuously forces the surface of the fibrous sheet 18 opposite the contact point to contact the melt of the semiconductor material 16.

Even when the guide member 20 is rotatable about the axis, such as in the embodiment described immediately above, the method typically further comprises pulling the fibrous sheet 18 in a direction generally tangential to the contact point between the guide member 20 and the second surface of the fibrous sheet 18. Such pulling typically prevents prolonged contact between the surface of the fibrous sheet 18 and the melt of the semiconductor material 16, and prevents wrinkling or other undesirable distortion of the fibrous sheet 18 because pulling the fibrous sheet 18 generally keeps the fibrous sheet 18 taut.

When the guide member 20 is rotatable about its axis and the guide member 20 guides the fibrous sheet 18 in part by rotating, and when the method comprises pulling the fibrous sheet 18, the guide member 20 may be rotated merely from pulling the fibrous sheet 18. For example, pulling the fibrous sheet 18 in a direction generally tangential to the contact point between the guide member 20 and the second surface of the fibrous sheet 18 generally induces or otherwise initiates rotation of the guide member 20.

Alternatively, the guide member 20 may be rotated independent of the pulling of the fibrous sheet 18. For example, the guide member 20 may be coupled to a coupling member for enabling rotation of the guide member 20. The coupling member may be coupled to any portion of the guide member 20 so long as the guide member 20 is capable of rotation and so long as the coupling member does not inhibit the formation of the sheet of semiconductor material 14 on the surface of the fibrous sheet 18. In certain embodiments, the first coupling member is coupled to an end of the guide member 20. The coupling member may rotate the guide member 20 via a motor or another suitable method of providing rotational drive torque, such as manual rotation.

When the guide member 20 is rotated independent of the pulling of the fibrous sheet 18, an angular speed at which the guide member 20 rotates and a speed at which the fibrous sheet 18 is pulled are typically selected so as to prevent the fibrous sheet 18 from bending, wrinkling, or folding. Said differently, the guide member 20 is typically not rotated at a faster rate (or a slower rate) than a rate at which the fibrous sheet 18 is pulled to ensure that the fibrous sheet 18 remains taut. The particular angular speed utilized is contingent on numerous factors, including the desired thickness of the sheet of semiconductor material 14, and the configuration of the guide member 20, including its shape and diameter.

The fibrous sheet 18 may be pulled by various methods regardless of whether the guide member 20 is rotatable about its axis. For example, the fibrous sheet 18 may be pulled via manual tension. Alternatively, the fibrous sheet 18 may be pulled by a motor. For example, as shown in FIG. 2, the fibrous sheet 18 may be disposed between two opposing cylinders 26 once the surface of the fibrous sheet 18 has the sheet of semiconductor material 14 in contact therewith. One or both of the cylinders 26 may be driven by a motor, causing rotation of one or both of the cylinders 26, which in turn creates a pulling force on the fibrous sheet 18. In such an embodiment, the fibrous sheet 18 is generally in intimate contact with both of the cylinders 26 to provide an adequate tensile force to continuously pull the fibrous sheet 18. Such a method is desirable over manual tension because motors eliminate speed variations typically associated with manual tension. The cylinders 26 need not comprise the refractory materials of the guide member 20. Instead, the cylinders 26 are typically formed from a silicone composition which includes a metal filler, e.g. iron oxide, for modifying heat transfer properties of the rollers. Alternatively, the cylinders 26 may comprise fiber glass felts and fabrics, or conventional millboard rollers comprising various clays, fibers, and/or mica flakes.

Baffles (not shown) may be utilized in the system 10 between the guide member 20 and the opposing cylinders. The baffles are typically utilized to minimize thermal radiation of various components of the system 10 from heat of the melt of the semiconductor material 16 16.

The particular speed at which the fibrous sheet 18 is pulled is contingent on numerous factors, including the desired thickness of the sheet of semiconductor material 14, and the configuration of the guide member 20, including its shape and diameter.

In certain embodiments, the speed at which the fibrous sheet 18 is pulled and/or the angular speed at which the guide member 20 rotates (if rotatable about its axis) may independently be modified (i.e., increased or decreased) before, during, and/or after contacting the surface of the fibrous sheet 18 and the melt of the semiconductor material 16.

The guide member 20 may optionally be vibrated as the fibrous sheet 18 contacts the melt of the semiconductor material 16. Typically, the guide member 20 is maintained essentially stationary relative to any axis perpendicular to the axis of the guide member 20, i.e., the guide member 20 is stationary but for any rotation.

As shown in FIG. 2, the fibrous sheet 18 may be on a spool 28 such that as the fibrous sheet 18 is pulled in a direction generally tangential to the contact point between the guide member 20 and the second surface of the fibrous sheet 18, the spool 28 rotates and continuously feeds the fibrous sheet 18 to the guide member 20. If desired, the spool 28 may also be connected to a motor, or the spool 28 may merely rotate via the pulling force applied to the fibrous sheet 18 and/or via the rotation force from the guide member 20, if any. Alternatively, the fibrous sheet 18 may be provided in other forms and may be fed to the guide member 20 via numerous different methods, e.g. manually or mechanically feeding the fibrous sheet 18 to the guide member 20.

The length of time or time period during which the melt of the semiconductor material 16 is in contact with the surface of the fibrous sheet 18 is typically sufficient to allow the sheet of semiconductor material 14 to at least partially solidify. Because the method may be a continuous process such that the surface of the fibrous sheet 18 is continuously in contact with the melt of the semiconductor material 16, the time period during which a particular portion of the fibrous sheet 18 that is in contact with the melt of the semiconductor material 16 is typically sufficient to allow the sheet of semiconductor material 14 to at least partially solidify. This time period may be varied appropriately based on various parameters, such as various temperatures and heat transfer properties of the system 10, as well as the desired properties, e.g. thickness, of the sheet of semiconductor material 14. The time period is typically from greater than 0 to 30 seconds. However, this time period does not account for the time period during which the sheet of semiconductor material 14 may be in contact with the fibrous sheet 18 after its formation, which may extend significantly beyond 30 seconds contingent on when and whether the sheet of semiconductor material 14 is separated from the fibrous sheet 18.

Prior to and during the method, the bulk temperature of the melt of the semiconductor material 16 (T_{S}) is greater than or equal to a melting point temperature of the semiconductor material utilized (T_{M}) such that (T_{S})≧(T_{M}). In embodiments where the melt of the semiconductor material 16 comprises silicon, the bulk temperature of the molten silicon may range from 1414 to 1550, alternatively from 1450 to 1490° C., e.g. 1460° C.

The external surfaces of the guide member 20 and the fibrous sheet 18 may independently have a selectively controlled temperature, e.g. the external surfaces of the guide member 20 and the fibrous sheet 18 may independently be cooled and/or heated, or the external surfaces of the guide member 20 and the fibrous sheet 18 may merely have ambient temperatures (collectively (T_{F})). Typically, the external surfaces of the guide member 20 and the fibrous sheet 18 have substantially the same temperature. The temperature of the external surfaces of the guide member 20 and the fibrous sheet 18 prior to the surface of the fibrous sheet 18 contacting the melt of the semiconductor material 16 is less than the bulk temperature of the melt of the semiconductor material 16 ((T_{F})<(T_{S})) and also less than the melting point temperature of the semiconductor material utilized ((T_{F})<(T_{M})) such that a temperature difference between the external surfaces of the guide member 20 (and fibrous sheet 18) and the melt of the semiconductor material 16 will induce a liquid-to-solid phase transformation of the melt of the semiconductor material 16 on the surface of the fibrous sheet 18. As noted above, to maintain a desired temperature of the external surfaces of the guide member 20, the guide member 20 may be continuously cooled during the method.

The temperature (T_{F}) of the external surfaces of the guide member 20 (and the fibrous sheet 18 when the external surfaces of the guide member 20 and the fibrous sheet 18 have substantially the same temperature) is typically from greater than 0 to 500, alternatively from 100 to 400, alternatively from 100 to 200, ° C. The magnitude of the temperature difference between (T_{F}) and (T_{S}) can affect the microstructure and other properties of the sheet of semiconductor material 14. The temperature gradient between (T_{F}) and (T_{S}) which may be on the order of, for example, 800° C. or more.

In addition to controlling the temperature gradient of the external surfaces of at the guide member 20 and the fibrous sheet 18, as well as the temperature of the melt of the semiconductor material 16, the temperature of the radiant environment, such as a wall of the vessel 22, may also be controlled.

A composition of an atmosphere surrounding the system 10 can be controlled before, during, and/or after contacting the surface of the fibrous sheet 16 and the melt of the semiconductor material 16. For example, utilizing vitreous silica for the refractory materials of the guide member 20 and/or the vessel 22 may lead to oxygen contamination of the sheet of semiconductor material 14. Accordingly, oxygen contamination may be mitigated or substantially mitigated, by melting the semiconductor material and forming the sheet of semiconductor material 14 in a low-oxygen environment, comprising, for example, a dry mixture of hydrogen (e.g., less than 1 ppm water) and an inert gas such as argon, krypton or xenon. A low-oxygen environment may include one or more of hydrogen, helium, argon, or nitrogen. In one exemplary embodiment, the atmosphere may be chosen from an Ar/1.0 wt % H₂ mixture or an Ar/2.5 wt % H₂ mixture. In such embodiments, the system 10 is generally a closed system, i.e., the atmosphere of the system 10 is not influenced by its surroundings.

The sheet of semiconductor material 14 may be removed or separated from the surface of the fibrous sheet 18 using, for example, porosity of the fibrous sheet 18, differential expansion and/or mechanical assistance. Alternatively, the sheet of semiconductor material 14 may remain on the surface of the fibrous sheet 18 so as to provide the laminate 12, which is a supported article of semiconductor material. The laminate 12 may be useful for supporting the sheet of semiconductor material 14 during storage, transportation, and/or further processing of the sheet of semiconductor material 14 into a semiconductor wafer and/or photovoltaic cell. Typically, however, the sheet of semiconductor material 14 is easily separated from the fibrous sheet 18. As such, the laminate 12 formed from the method may only exist for an ephemeral period of time when the method comprises separating the sheet of semiconductor material 14 from the fibrous sheet 18. The fibrous sheet 18 may be continuously spooled or collected once the sheet of semiconductor material 14 is separated therefrom, or the laminate 12 itself may be spooled or collected.

The method may be operated as a batch method or a continuous method. In the continuous method, the fibrous sheet 18 is typically continuously guided by the guide member 20 as the surface of the fibrous sheet 18 contacts the melt of the semiconductor material 16. In such embodiments, the melt of the semiconductor material 16 may be continuously replenished so as to maintain a constant surface level of the melt of the semiconductor material 16, or the guide member 20 may be continuously lowered into the vessel 22 containing the melt of the semiconductor material 16 as the surface level of the melt of the semiconductor material 16 decreases. In such embodiments, the laminate 12, or the fibrous sheet 18 if separated from the sheet of semiconductor material 14, may be spooled or otherwise collected.

In certain embodiments, it may be desirable to modify the grain structure of the resulting sheet of semiconductor material 14. To this end, the method may further comprise at least partially remelting the sheet of semiconductor material 14 to form a remelted semiconductor material and recrystallizing the remelted semiconductor material.

The thickness of the sheet of semiconductor material 14 is a function of, among other things, the guide member 20 utilized, the angular speed of the guide member 20, if rotated, the rate at which the fibrous sheet 18 is pulled, and the time period during which the melt of the semiconductor material 16 is in contact with the surface of the fibrous sheet 18. In certain embodiments, the thickness of the sheet of semiconductor material 14 is from 20 to 500, alternatively 100 to 400, alternatively from 125 to 350, alternatively from 150 to 300, alternatively from 175 to 250, microns. Notably, the parameters of the method may be selectively controlled to obtain sheets of semiconductor materials having a thickness that is less than what is currently possible in conventional methods, such as exocasting. As such, in certain embodiments, the thickness of the sheet of semiconductor material 14 is from 20 to 100, alternatively 20 to 80, alternatively from 20 to 60, microns. Further, sheet of semiconductor material 14 has a total thickness variability (TTV) of less than 30, alternatively less than 25, alternatively less than 20, alternatively less than 15, alternatively less than 10, alternatively less than 5, alternatively less than 4, alternatively less than 3, alternatively less then 2, alternatively less than 1, percent. TTV means the normalized maximum difference in thickness between the thickest point and the thinnest point within a sampling area of a solid layer. TTV is equal to (tₘₐₓ−tₘᵢₙ)/t_{target}, where tₘₐₓ and tₘᵢₙ are the maximum and minimum thicknesses within the sampling area and t_{target} is the target thickness. The sampling area may be defined as the whole or a portion of the solid layer. TTV may be measured in accordance with ASTM F657-92 (1999).

If desired, the physical dimensions of the sheet of semiconductor material 14 may also be modified by altering the system 10 itself, e.g. altering the fibrous sheet 18. For example, as noted above, the sheet of semiconductor material 14, once separated from the fibrous sheet 18, desirably has a surface texture that corresponds to a surface texture of the fibrous sheet 18 imparted by the fiber(s).

The disclosed methods can be used to produce solid layers of semiconductor material having one or more desired attributes related to, for example, total thickness, TTV, impurity content and/or surface roughness. These solid layers, such as silicon sheets, may be used to for electronic devices, e.g. photovoltaic devices. By way of example, an as-formed silicon sheet may have real dimensions of about 156 mm×156 mm, a thickness in a range of 100 μm to 400 μm, and a substantial number of grains larger than 1 mm.

Conventional methods, such as various exocasting methods in which a mold is submersed and withdrawn from a melt of a semiconductor material, have been utilized to form solid layers of semiconductor materials. However, in such exocasting methods, the preparation of solid layers of semiconductor materials is typically time consuming, because the solid layers of semiconductor materials formed therefrom have limited dimensions due to sizes of the molds utilized and limitations on the sizes of molds utilized attributable to heat transfer properties. However, the instant system 10 and method can prepare solid layers of semiconductor materials in a continuous fashion, thus obviating deficiencies of conventional exocasting methods.

Other conventional methods have also utilized casting methods in which an external surfaces of a mold or a wheel is contacted with a melt of a semiconductor material to form solid layers of semiconductor materials. However, these prior methods are limited in that the solid layers of semiconductor materials also have limited dimensions. For example, the solid layers of semiconductor materials must be stripped or otherwise separated from the surface of the mold or wheel prior to reusing the mold or wheel to form another solid layer of semiconductor material. However, the instant system 10 and method can prepare sheets of semiconductor material 14 in a continuous fashion, thus obviating deficiencies of conventional exocasting methods.

Further, in certain electronic components, such as photovoltaic cell modules, it is desirable to impart solid layers of semiconductor materials with surface roughness. This typically requires refining or otherwise altering solid layers of semiconductor materials formed from prior methods prior to their end use. However, the instant system 10 and method prepare solid layers of semiconductor materials already possessing desirable surface roughness and texturization in view of the surface roughness imparted by the fiber(s) of the fibrous sheet 18, thereby eliminating further processing steps conventionally required.

The sheet of semiconductor material 14 may define one or more (e.g. up to 30) apertures therethrough. The apertures may enable the sheet of semiconductor material 14 defining such apertures to be used to prepare a metallization wrap-through photovoltaic cell.

The sheet of semiconductor material 14 may be utilized in various applications and components, such as electronic components or devices comprising the sheet of semiconductor material 14. For example, the sheet of semiconductor material 14 may be utilized in integrated circuits, light emitting diodes, photovoltaic cells, microprocessors, and other electronic components, which may be incorporated into computers, digital cameras, and photovoltaic cell modules.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

The following examples are intended to illustrate embodiments and are not to be viewed in any way as limiting to the scope of the disclosure.

### EXAMPLES

### Example 1

A system in accordance with the disclosure comprises, as the guide member, a cylindrical roller rotatable about an axis, as illustrated in FIG. 1. The fibrous sheet and the cylindrical roller each comprise vitreous silica. The melt of the semiconductor material comprises molten silicon.

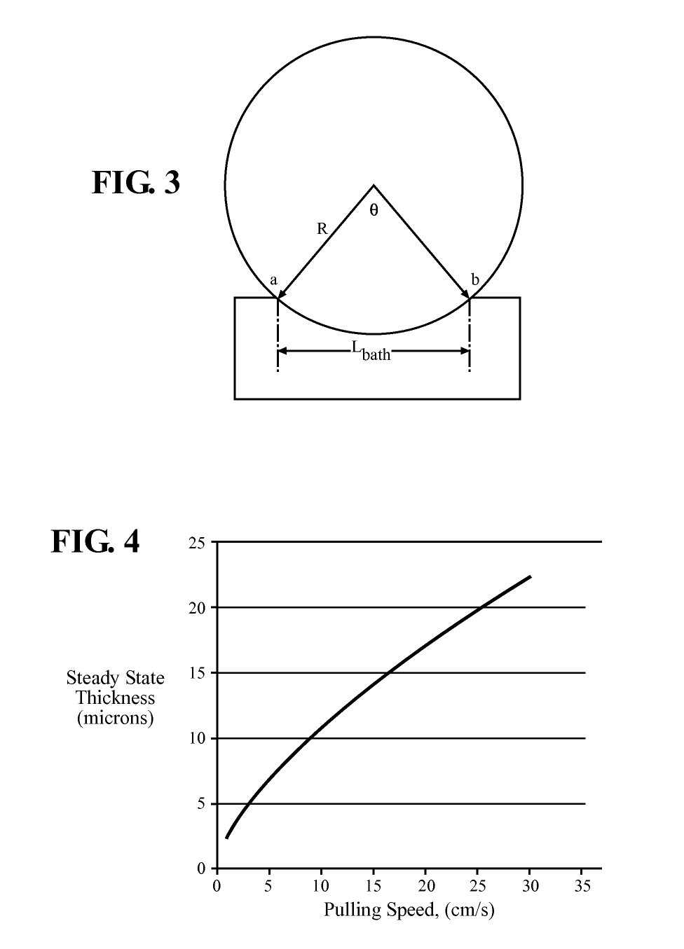

With reference to FIG. 3, the residence time of the fibrous sheet as it contacts the melt of the semiconductor material can be calculated as follows:

$$τ = \frac{2 {sin}^{- 1} \frac{{L}_{bath}}{2 R}}{ω}$$

where L_{bath} is the width of the fibrous sheet that contacts the melt of the semiconductor material (also referred to as the lateral length of the melt of the semiconductor material), R is the radius of the guide member, and w is the angular speed at which the guide member rotates (in radians per second (rad/s)). The fibrous sheet generally contacts the melt of the semiconductor material at point “a” and no longer is in contact with the melt of the semiconductor material at point “b.”

When the residence time of the fibrous sheet is smaller than a meltback time of the solid layer of semiconductor material formed on the fibrous sheet via the method, a continuous solidified sheet exists across the lateral length of the melt of the semiconductor material. When the rotational speed of the guide member is about 120 rotations per minute (rpm), the radius of the guide member is 2.5 centimeters (cm), and the angle θ is 88 degrees, the sheet of semiconductor material so formed has a thickness of from about 5 to about 50 microns depending on the thermal properties of the fibrous sheet.

However, when the residence time is larger than that required for meltback of the solid layer of semiconductor material formed on the fibrous sheet via the method, then a continuous solidified sheet does not exist across the lateral length of the melt of the semiconductor material. In that case, however, a solid layer of semiconductor material is still formed due to viscous dragging of the melt of the semiconductor material by the fibrous sheet. The minimum thickness of the dragged melt, which forms the sheet of semiconductor material, is given by the steady state thickness of the Landau-Levich meniscus. The calculated thickness of the Landau-Levich thickness is shown in FIG. 4 as a function of a pulling speed of the fibrous sheet. As but one example, the thickness of the sheet of semiconductor material at a linear speed of about 30 centimeters per second (cm/s) is about 20 microns.

As used herein, the singular forms “a,” “an” and “the” include plural referents unless the context clearly dictates otherwise. Thus, for example, reference to a “fibrous sheet” includes examples having two or more such “fibrous sheets” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a laminate comprising a sheet of semiconductor material include embodiments where a laminate consists of a sheet of semiconductor material and embodiments where a laminate consists essentially of a sheet of semiconductor material.

It is also noted that recitations herein refer to a component being “configured” or “adapted to” function in a particular way. In this respect, such a component is “configured” or “adapted to” embody a particular property, or function in a particular manner, where such recitations are structural recitations as opposed to recitations of intended use. More specifically, the references herein to the manner in which a component is “configured” or “adapted to” denotes an existing physical condition of the component and, as such, is to be taken as a definite recitation of the structural characteristics of the component.

What is claimed is:

1. A method of forming a laminate comprising a sheet of semiconductor material, said method employing a system which comprises a fibrous sheet, a guide member for guiding the fibrous sheet, and a melt of a semiconductor material, said method comprising contacting an undersurface of the fibrous sheet with the melt of the semiconductor material as the fibrous sheet is guided by the guide member such that the sheet of semiconductor material is formed on the undersurface of the fibrous sheet to give the laminate comprising the sheet of semiconductor material in contact with the undersurface of the fibrous sheet.

2. A method of forming a laminate comprising a sheet of semiconductor material, said method employing a system which comprises a fibrous sheet, a guide member for guiding the fibrous sheet, and a melt of a semiconductor material, said method comprising contacting a surface of the fibrous sheet with the melt of the semiconductor material as the fibrous sheet is guided by the guide member such that the sheet of semiconductor material is formed on the surface of the fibrous sheet to give the laminate comprising the sheet of semiconductor material in contact with the surface of the fibrous sheet;
wherein the fibrous sheet comprises a material selected from fused silica, silicon nitride, mullite, magnesium aluminate, and combinations thereof.

3. A method as set forth in claim 1, wherein the guide member comprises a convex member extending along an axis.

4. A method as set forth in claim 3 wherein the convex member is rotatable about the axis.

5. A method as set forth in claim 1, wherein a second surface of the fibrous sheet opposite the surface that contacts the melt of the semiconductor material is in contact with the guide member such that a portion of the fibrous sheet is disposed between the guide member and the melt of the semiconductor material.

6. A method as set forth in claim 5, wherein the system defines a contact point between the fibrous sheet and the guide member where the second surface of the fibrous sheet contacts the guide member, and wherein said method further comprises pulling the fibrous sheet in a direction generally tangential to the contact point as the guide member guides the fibrous sheet and the sheet of semiconductor material is formed on the surface of the fibrous sheet.

7. A method as set forth in claim 1 wherein (a) the fibrous sheet is woven; (b) the fibrous sheet is non-woven; (c) the fibrous sheet comprises a material selected from fused silica, silicon nitride, mullite, magnesium aluminate, and combinations thereof; (d) both (a) and (c); or (e) both (b) and (c).

8. A method as set forth in claim 1, further comprising the step of separating the sheet of semiconductor material and the fibrous sheet from one another.

9. A method as set forth in claim 1, wherein (a) the guide member comprises a surface material selected from fused silica, graphite, silicon nitride, single crystal silicon, polycrystalline silicon, and combinations thereof; (b) the sheet of semiconductor material has a thickness of from 25 to 300 microns; (c) the sheet of semiconductor material comprises a material selected from silicon, germanium, composites thereof, and combinations thereof; (d) the guide member has a temperature T_{F} and the melt of the semiconductor material has a temperature T_{S} such that T_{S}>T_{F}; or (e) any combination of (a)-(d).

10. A system for forming a sheet of semiconductor material in accordance with the method of claim 1, the system comprising a fibrous sheet, a guide member for guiding the fibrous sheet, and a melt of a semiconductor material.

11. A laminate comprising a sheet of semiconductor material in contact with an undersurface of a fibrous sheet formed in accordance with the method of claim 1.

12. A sheet of semiconductor material formed in accordance with the method of claim 1.
